(19) United States
(12) Patent Application Publication
(10) Pub. No.: US 2007/0244587 A1
(43) Pub. Date: Oct. 18, 2007

(54) Sound Volume Converting Apparatus

(75) Inventor: Yasunori Yamamoto, Gunma-ken (JP)

Correspondence Address: SoCAL IP LAW GROUP LLP, 310 N. WESTLAKE BLVD. STE 120, WESTLAKE VILLAGE, CA, 91362, US

(73) Assignee: Sanyo Electric Co., Ltd., Osaka (JP)

(21) Appl. No.: 11/734,754

(22) Filed: Apr. 12, 2007

(30) Foreign Application Priority Data
Apr. 13, 2006 (JP) 2006-111317

(51) Int. Cl. G06F 17/00; H03G 3/00

(52) U.S. Cl. 700/94; 381/104

(57) ABSTRACT

A sound volume converting apparatus comprises a data shift unit configured to shift digital audio data by a predetermined number of bits to the right based on first sound volume adjustment data; a correction value calculating unit configured to calculate a correction value based on the right-shifted digital audio data and second sound volume adjustment data; and an adding unit configured to add the correction value to the right-shifted digital audio data to be output.

### CROSS-REFERENCE TO RELATED APPLICATION

This application claims the benefit of priority to Japanese Patent Application No. 2006-111317, filed Apr. 13, 2006, of which full contents are incorporated herein by reference.

### BACKGROUND OF THE INVENTION

1. Field of the Invention

The present invention relates to a sound volume converting apparatus.

2. Description of the Related Art

Recently, various digital devices are digitally controlled. In such digital audio devices, audio data is handled as digitalized data (hereinafter, digital audio data), and sound volume adjustment at the time of reproduction is performed by converting a value of the digital audio data. Various technologies are developed for this purpose (see, e.g., Japanese Patent Application Laid-Open Publication No. 1993-235667).

By the way, it is known as characteristics of the human that increase and decrease of a volume of sound heard are not felt proportionally to a sound volume difference and are felt proportionally to the logarithm of the sound volume difference.

Therefore, when a volume of sound output from an audio device is exponentially increased or decreased, the volume of sound heard is linearly increased or decreased for human ears.

Therefore, in a conventional digital audio device, for example, as shown in FIG. 9, a gain setting value (sound volume adjustment data) is stored at each address of a ROM 1200 to read a gain setting value from a corresponding address in accordance with sound volume adjustment operation of a user, and a multiplier 1100 is used to multiply the gain setting value by a PCM (Pulse Code Modulation) audio signal (digital audio data) to exponentially change the value of the original digital audio data in accordance with the sound volume adjustment operation of the user.

Alternatively, as shown in FIG. 10, the gain setting value is directly input to the multiplier 1100 and the digital audio data is converted with the multiplier 1100 in some cases.

However, in the case of the configuration of FIG. 9, since the ROM 1200 is required for storing all the data from data for minimizing the sound volume to data for maximizing the sound volume and the multiplier 1100 is also needed, miniaturization of a circuit scale is prevented. In the case of the configuration of FIG. 10, although the ROM 1200 is not needed, a generation circuit is necessary for generating the gain setting value in accordance with the sound volume adjustment operation of the user. Generally, since the number of bits of the gain setting value is greater than that of the address, a high load is applied to the generation circuit. Furthermore, since the multiplier 1100 is needed, miniaturization of a circuit scale is difficult.

### SUMMARY OF THE INVENTION

The present invention was conceived in view of the above problems and it is therefore the object of the present invention to provide a sound volume converting apparatus with a configuration not requiring a ROM and an adder.

In order to achieve the above object, according to an aspect of the present invention there is provided a sound volume converting apparatus that comprises a data shift unit configured to shift digital audio data by a predetermined number of bits to the right based on first sound volume adjustment data; a correction value calculating unit configured to calculate a correction value based on the right-shifted digital audio data and second sound volume adjustment data; and an adding unit configured to add the correction value to the right-shifted digital audio data to be output.

Other features of the present invention will become apparent from descriptions of this specification and of the accompanying drawings.

### BRIEF DESCRIPTION OF THE DRAWINGS

For more thorough understanding of the present invention and advantages thereof, the following description should be read in conjunction with the accompanying drawings, in which:

FIG. 1 is a diagram of a configuration of an audio system according to an embodiment.

FIG. 2 is a diagram of an outline of a process in a gain controller according to an embodiment.

FIG. 3 is a diagram of a circuit configuration of the gain controller according to an embodiment.

FIG. 4 is a diagram of a timing chart of a process in the gain controller according to an embodiment.

FIG. 5 is a diagram of sound volume controlled by the gain controller according to an embodiment.

FIG. 6 is a diagram of sound volume adjustment data according to an embodiment.

FIG. 7 is a diagram of sound volume adjustment data according to an embodiment.

FIG. 8 is a diagram of a sound volume controlled by the gain controller according to an embodiment.

FIG. 9 is a diagram of an example of a sound volume converting apparatus.

FIG. 10 is a diagram of an example of a sound volume converting apparatus.

### DETAILED DESCRIPTION OF THE INVENTION

At least the following details will become apparent from descriptions of this specification and of the accompanying drawings.

==Overall Configuration==

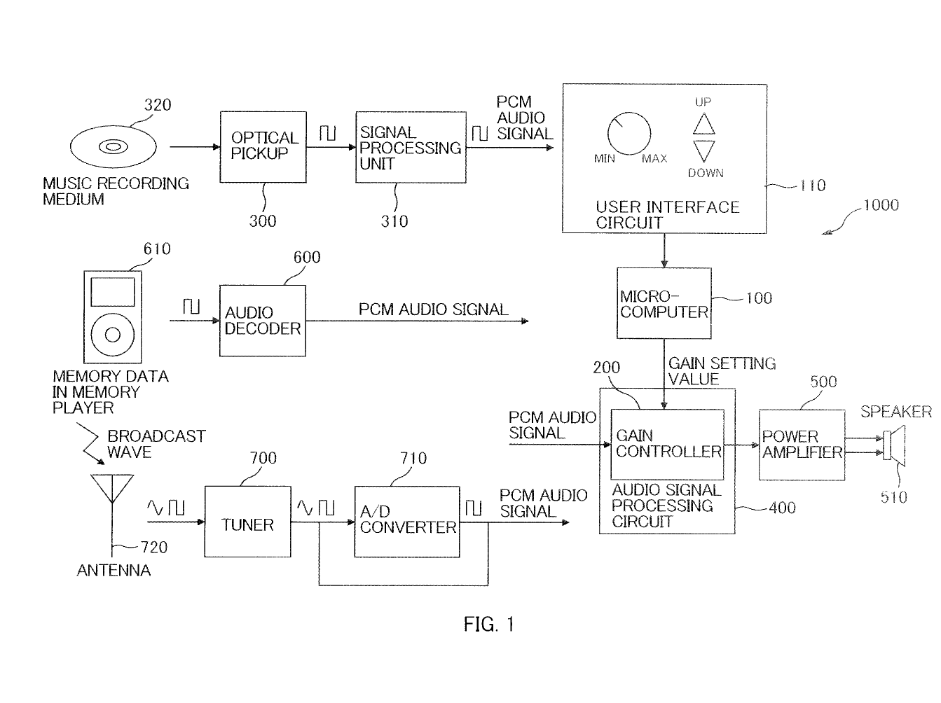

An overall configuration of an audio system 1000 according to an embodiment will be described with reference to FIG. 1. The audio system 1000 can be general-purpose audio, portable audio, television, and radio, for example. Of course, these devices may be configured as one audio system 1000.

The audio system 1000 includes a user interface circuit 110, a microcomputer 100, an audio signal processing circuit 400, a power amplifier 500, and a speaker 510. Additionally, in the case of the general-purpose audio, an optical pickup 300 and a signal processing unit 310 are included. In the case of the portable audio, an audio decoder 600 is included. In the case of the television or radio, an antenna 720, a tuner 700, and an A/D converter 710 are included.

The optical pickup 300 is an apparatus that detects reflected light of light applied to a music recording medium 320 to read audio data recorded in the music recording medium 320.

The signal processing unit 310 is a circuit that demodulates the read audio data to output a PCM audio signal (digital audio data). The signal processing unit 310 is configured by a DSP (Digital Signal Processor) and a DIR (Digital Audio Interface Receiver), for example.

The audio decoder 600 is a circuit that decodes the audio data recorded in a memory player 610 to output the PCM audio signal.

The antenna 720 is an apparatus that receives electric wave such as AM, FM, TV, etc.

The tuner 700 is a circuit that detects the received electric wave. When receiving electric wave of digital broadcasting, the tuner 700 outputs the PCM audio signals, and when receiving electric wave of analog broadcasting, the tuner 700 outputs analog audio signals.

The A/D converter 710 is an apparatus that converts the analog signal output from the tuner 700 into the PCM audio signal.

The user interface circuit 110 is a circuit that accepts operational input for sound volume adjustment from a user to output a signal for adjusting sound volume to the microcomputer 100.

The microcomputer 100 is an apparatus that outputs a gain setting value (corresponding to sound volume adjustment data of claims) to the audio signal processing circuit 400 in response to the input of the signal for adjusting sound volume.

The audio signal processing circuit 400 is a circuit that performs processes, such as conversion of sound volume and adjustment of frequency characteristics, in response to the input of the PCM audio signal. The conversion of sound volume is performed by converting the PCM audio signal with a gain controller 200 configuring the audio signal processing circuit 400 in accordance with the gain setting value. Details will be described later.

The power amplifier 500 is a circuit that amplifies and outputs the analog audio signals or the PCM audio signals output from the audio signal processing circuit 400.

The speaker 510 is an apparatus that converts the electric signals output from the power amplifier 500 into sound, which is output.

The PCM audio signal corresponds to digital audio data of claims. The gain setting value corresponds to sound volume adjustment data of claims.

==Gain Controller==

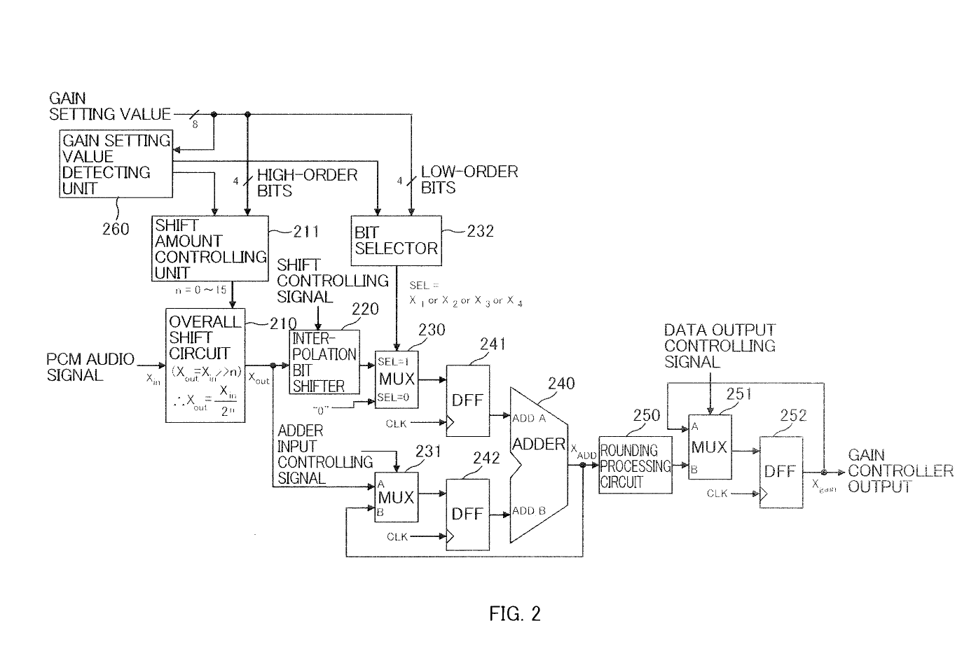

The gain controller 200 will be described with reference to FIGS. 2 to 8.

<Configuration>

A configuration of the gain controller 200 will be described with reference to FIG. 2.

The gain controller 200 according to an embodiment includes a shift amount controlling unit 211, an overall shift circuit 210, an interpolation bit shifter 220, a bit selector 232, multiplexers 230, 231, D-flip-flops 241, 242, an adder 240, a rounding processing circuit 250, a multiplexer 251, a D-flip-flop 252, and a gain setting value detecting unit 260.

The gain setting value output from the microcomputer 100 and the PCM audio signal is input to the gain controller 200. The gain controller 200 outputs the PCM audio signal converted with the gain setting value.

In an embodiment, the gain setting value is assumed to be eight bits, for example. The PCM audio signal is assumed to be 24 bits for example.

The gain setting value detecting unit 260 determines allocations of the number of bits input to the shift amount controlling unit 211 and the number of bits input to the bit selector 232 among the bits of the gain setting value in accordance with the gain setting value and gives instructions to the shift amount controlling unit 211 and the bit selector 232.

The shift amount controlling unit 211 accepts, for example, high-order four bits (hereinafter, first sound volume adjustment data) of the gain setting value in accordance with the instruction from the gain setting value detecting unit 260 and outputs the number of bits, by which the PCM audio signal is shifted, based on the first sound volume adjustment data.

The overall shift circuit 210 shifts each bit of the PCM audio signal toward the lower-order bits (to the right) by the bit number output from the shift amount controlling unit 211. For simplicity of description, the PCM audio signal input to the overall shift circuit 210 is represented by Xᵢₙ, and the PCM audio signal shifted by the overall shift circuit 210 is represented by Xₒᵤₜ, Xₒᵤₜ is input to the interpolation bit shifter 220 and the multiplexer 231 described later.

The interpolation bit shifter 220 sequentially shift Xₒᵤₜ toward lower-order bits by one bit at a time in accordance with the shift control signal and outputs intermediate data each time.

The bit selector 232 accepts, for example, low-order four bits (hereinafter, second sound volume adjustment data) of the gain setting value in accordance with the instruction from the gain setting value detecting unit 260 and outputs a value of each bit of the second sound volume adjustment data in the order from the highest-order bit each time the interpolation bit shifter 220 shifts Xₒᵤₜ and outputs the intermediate data. The values of the bits of the second sound volume adjustment data are represented by X1, X2, X3, and X4 in the order from the highest-order bit.

The multiplexer 230 outputs the intermediate data output from the interpolation bit shifter 220 if the value output from the bit selector 232 is one, and outputs zero if the value output from the bit selector 232 is zero.

The D-flip-flop 241 outputs the data (intermediate data or zero) output from the multiplexer 230 in synchronization with a clock signal (hereinafter, CLK).

The multiplexer 231 receives input of Xₒᵤₜ and an addition result output from the adder 240 described later, one of which is output in accordance with an adder input control signal.

The D-flip-flop 242 outputs the data (Xₒᵤₜ or addition result) output from the multiplexer 231 in synchronization with the clock signal.

The adder 240 adds the data output from the D-flip-flop 241 and the data output from the D-flip-flop 242. The addition result is input to the multiplexer 231. As a result, the data output from the D-flip-flop 241 is accumulated in the addition result of the adder 240.

The rounding processing circuit 250 performs a rounding process of the addition result.

The multiplexer 251 receives input of the addition result output from the rounding processing circuit 250 and the addition result output from the D-flip-flop 252 described later, one of which is output in accordance with a data output control signal.

The D-flip-flop 252 outputs the addition result output from the multiplexer 251 in synchronization with the clock signal.

<Sound Volume Control Process>

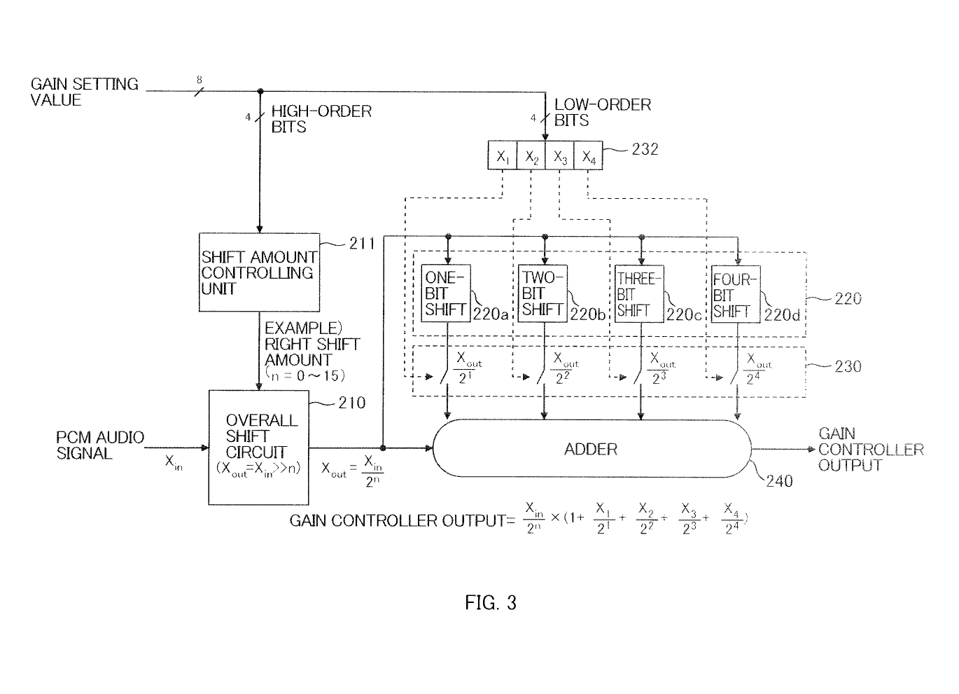

The sound volume control according to an embodiment will be described with reference to FIGS. 3 to 8.

Among the eight-bit gain setting value input to the gain controller 200, for example, high-order four bits are the first sound volume adjustment data and input to the shift amount controlling unit 211. The shift amount controlling unit 211 calculates data indicating the bit number n, by which the PCM audio signal is shifted, based on a value obtained by decoding the four-bit first sound volume adjustment data.

For example, if the first sound volume adjustment data is “1111”, the shift amount controlling unit 211 calculates n=0. In this case, the right shift amount of the PCM audio signal is zero bit. For example, if the first sound volume adjustment data is “0001”, the shift amount controlling unit 211 calculates n=14. In this case, the right shift amount of the PCM audio signal is 14 bits. The above calculation of n in the shift amount controlling unit 211 can be performed, for example, by configuring a logic circuit that performs decoding with attention to “0” in the first sound volume adjustment data or, for example, by configuring a logic circuit that subtracts a value obtained by decoding the first sound volume adjustment data with attention to “1” from 15 (two to the fourth power-1). That is, in the former case, “1111” is correlated with 0 in the decimal system and “0000” is correlated with 15 in the decimal system in the logic configuration of the decode circuit, and in the latter case, “0000” is correlated with 0 in the decimal system and “1111” is correlated with 15 in the decimal system. Of course, the above calculation of n in the shift amount controlling unit 211 may be performed with software.

Of course, the shift amount controlling unit 211 may use the value obtained by decoding the first sound volume adjustment data with attention to “1” for the right shift amount (n). In this case, if the first sound volume adjustment data is “1111”, n=15 is calculated. If the first sound volume adjustment data is “0001”, n=1 is calculated.

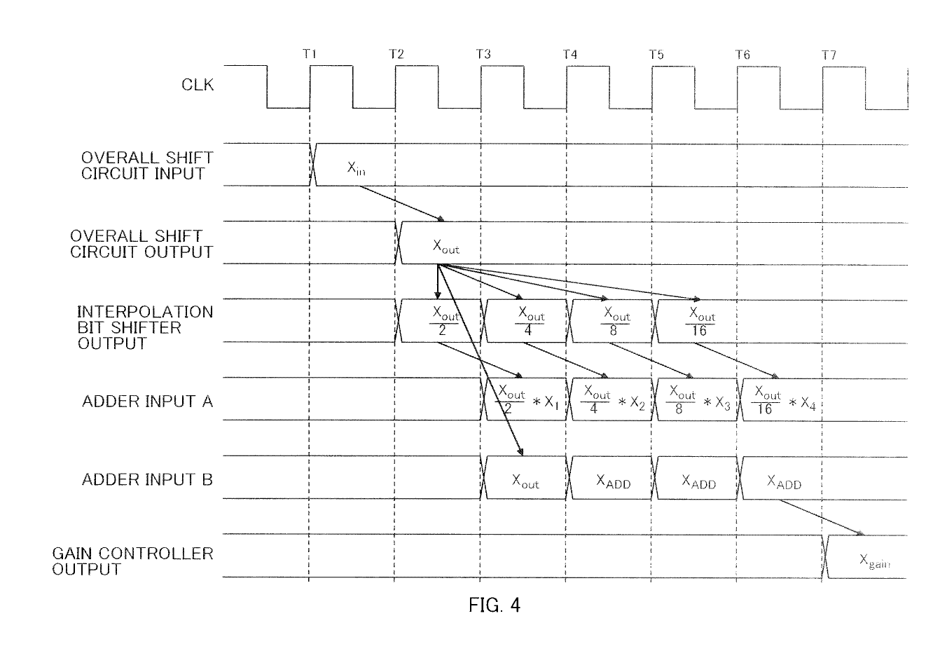

The overall shift circuit 210 outputs the PCM audio signal after shifting toward lower-order bits by the number of bits of the output n from the shift amount controlling unit 211. The PCM audio signal input to the overall shift circuit 210 is indicated by Xᵢₙ and the PCM audio signal output from the overall shift circuit 210 is indicated by Xₒᵤₜ. For example, if the PCM audio signal is eight-bit and Xᵢₙ is “11110000”, in the case of n=2, Xₒᵤₜ is “00111100”. As shown in FIG. 3, Xₒᵤₜ=Xᵢₙ/2̂n. The “2̂n” indicates 2 to the nth power. FIG. 4 shows a time chart of how Xᵢₙ is input to the overall shift circuit 210 and Xₒᵤₜ is output in synchronization with the clock signal (CLK). In an example shown in FIG. 4, Xᵢₙ is input to the overall shift circuit 210 at the clock signal rising edge indicated by T1 and Xₒᵤₜ is output at the clock signal rising edge indicated by T2.

Xₒᵤₜ output from the overall shift circuit 210 is input to the interpolation bit shifter 220.

The interpolation bit shifter 220 sequentially shift each bit of Xₒᵤₜ toward lower-order bits by one bit at a time for the number of times (in this case, four times) corresponding to the number of bits of the second sound volume adjustment data and sequentially outputs the obtained value as the intermediate data each time the shifting is performed.

FIG. 4 shows how the intermediate data is sequentially output. As shown in FIG. 4, Xₒᵤₜ is shifted toward lower-order bits by one bit at a time at the timing of each clock signal rising edge indicated by T2, T3, T4, and T5, and is output from the interpolation bit shifter 220 as the intermediate data.

The interpolation bit shifter 220 may be configured by four interpolation bit shifters 220a, 220b, 220c, and 220d as shown in FIG. 3. In this case, the interpolation bit shifters 220a, 220b, 220c, and 220d shift each bit of Xₒᵤₜ by the number of bits corresponding to the position of each bit of the second sound volume adjustment data. For example, the interpolation bit shifter 220a shifts Xₒᵤₜ by one bit to the right correspondingly to a position of the highest bit (X1) of the second sound volume adjustment data. The interpolation bit shifter 220b shifts Xₒᵤₜ by two bits to the right correspondingly to a position of a second bit (X2) from the highest bit of the second sound volume adjustment data. The interpolation bit shifter 220c shifts Xₒᵤₜ by three bits to the right correspondingly to a position of a third bit (X3) from the highest bit of the second sound volume adjustment data. The interpolation bit shifter 220d shifts Xₒᵤₜ by four bits to the right correspondingly to a position of a fourth bit (X4) from the highest bit of the second sound volume adjustment data.

As a result, the interpolation bit shifter 220a outputs intermediate data 1 (Xₒᵤₜ/2̂1) that is Xₒᵤₜ shifted by one bit toward lower-order bits. The interpolation bit shifter 220b outputs intermediate data 2 (Xₒᵤₜ/2̂2) that is Xₒᵤₜ shifted by two bits toward lower-order bits. The interpolation bit shifter 220c outputs intermediate data 3 (Xₒᵤₜ/2̂3) that is Xₒᵤₜ shifted by three bits toward lower-order bits. The interpolation bit shifter 220d outputs intermediate data 4 (Xₒᵤₜ/2̂4) that is Xₒᵤₜ shifted by four bits toward lower-order bits.

If the interpolation bit shifter 220 is configured by the four interpolation bit shifters 220a, 220b, 220c, and 220d, the intermediate data 1 to 4 may be output at the same timing (e.g., T2 of FIG. 4). Since time required for outputting all the intermediate data 1 to 4 is reduced in this case, the sound volume converting process can be performed at high speed.

By the way, the bit selector 232 sequentially outputs a value of each bit of the second sound volume adjustment data in the order from the highest-order bit each time the intermediate data 1 to 4 are output.

Therefore, only when the highest-order bit (X1) of the second sound volume adjustment data is “1”, the intermediate data 1 is output from the multiplexer 230 to the adder 240. Only when the second bit (X2) from the highest-order bit of the second sound volume adjustment data is “1”, the intermediate data 2 is output from the multiplexer 230 to the adder 240. Only when the third bit (X3) from the highest-order bit of the second sound volume adjustment data is “1”, the intermediate data 3 is output from the multiplexer 230 to the adder 240. Only when the fourth bit (X4) from the highest-order bit of the second sound volume adjustment data is “1”, the intermediate data 4 is output from the multiplexer 230 to the adder 240. This situation is shown in the time chart of FIG. 4. FIG. 4 shows that logical products of the intermediate data and the corresponding bits (X1 to X4) of the second sound volume adjustment data are sequentially output at the timings of the clock signal rising edges indicated by T3, T4, T5, and T6.

The adder 240 cumulatively adds Xₒᵤₜ output from the D-flip-flop 242 and the intermediate data output from the D-flip-flop 241 and outputs the addition result. The adder 240 can be realized only by hardware, only by software, or by a combination of hardware and software.

The time chart of FIG. 4 shows how the addition results are accumulated. In FIG. 4, the addition result is represented by X_{add}. As shown in FIG. 4, the intermediate data are sequentially accumulated at the timing of the clock signal rising edges indicated by T4, T5, T6, and T7, and the result is output at the timing of T7.

The addition result output from the adder 240 is output from the D-flip-flop 252 to the outside after the rounding process of the rounding processing circuit 250.

<Output Sound Volume>

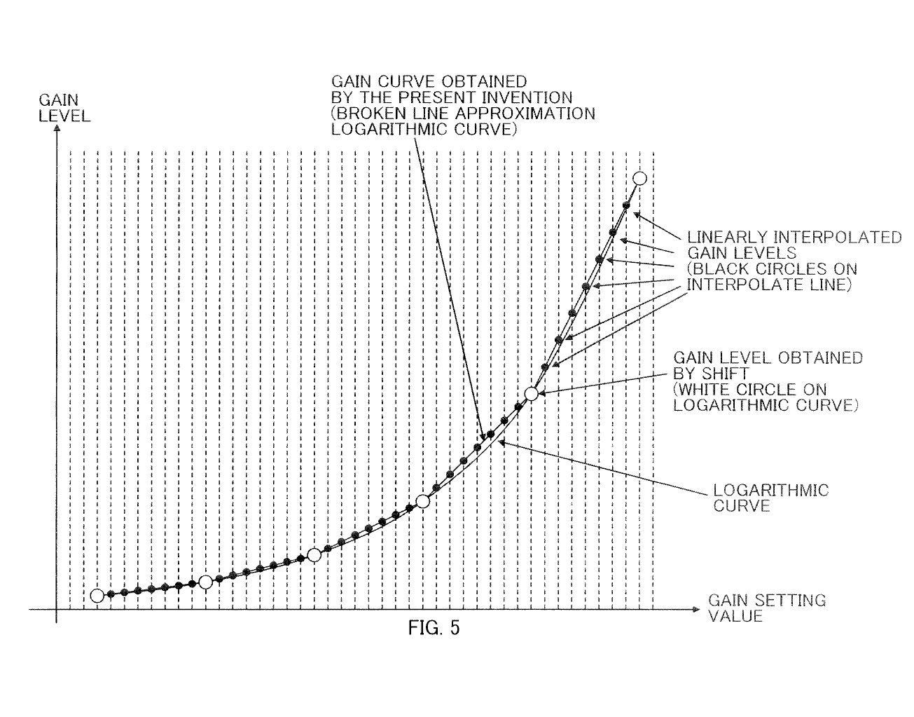

Description will be made of a sound volume output when the PCM audio signal is converted by the gain controller 200 of an embodiment with reference to FIG. 5. FIG. 5 is a graph of the ratio of the value of the PCM audio signal output from the gain controller 200 and the value of the PCM audio signal input to the gain controller 200 with the gain setting values as the horizontal axis and the gain levels as the vertical axis.

The PCM audio signal (Xᵢₙ) input to the gain controller 200 is shifted by the overall shift circuit 210 toward lower-order bits by the number of bits of the value (n) obtained based on the value obtained by decoding the first sound volume adjustment data. The value after the shift (Xₒᵤₜ) corresponds to a white circle of FIG. 5. The number of the white circles on the graph is dependent on the number of bits of the first sound volume adjustment data. For example, if the first sound volume adjustment data is four bits, the number of the white circles is 16 (two to the fourth power). A gain level of each white circle is doubled or decreased by half from a gain level of the adjacent white circle.

The output from the adder 240, i.e., a value obtained by adding a correction value to Xₒᵤₜ corresponds to a black circle of FIG. 5. As shown in FIG. 5, the black circles are arranged on points that equally divide a line linking the adjacent white circles. That is, the black circles linearly interpolate the white circles. The number of the black circles interpolating the adjacent white circles is dependent on the number of bits of the second sound volume adjustment data. For example, if the second sound volume adjustment data is four bits, the number of the black circles is 15 (two to the fourth power-1).

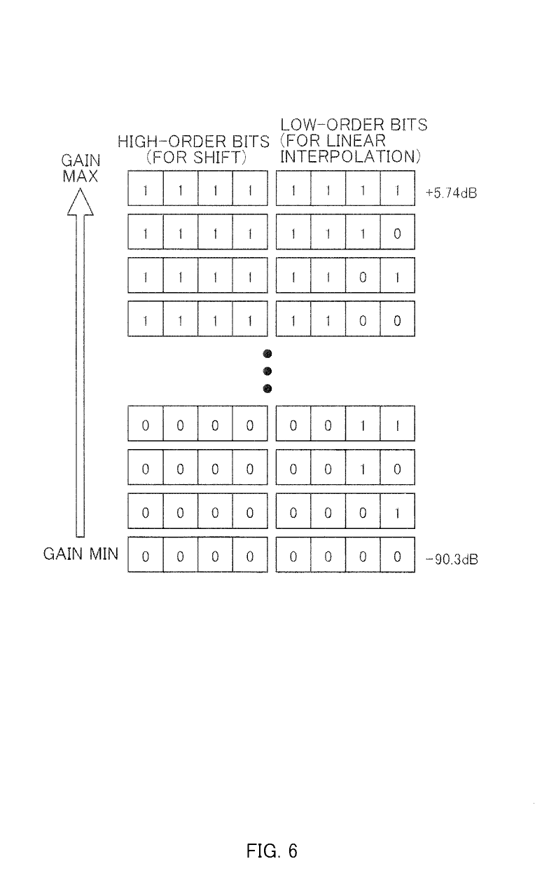

In this way, the gain is controlled by the sound volume adjustment data. FIG. 6 shows the sound volume adjustment data if the first sound volume adjustment data is four bits and the second sound volume adjustment data is four bits. In this case, the maximum gain is obtained when the sound volume adjustment data is “11111111” and is 5.74 dB ((1+15/16) times). The minimum gain is obtained when the sound volume adjustment data is “00000000” and is −90.3 dB ((2̂−15) times).

By the way, since the number of the white circles is dependent on the number of bits of the first sound volume adjustment data, the number of the white circles is increased if the number of bits of the first sound volume adjustment data is increased. Similarly, the number of the black circles is increased if the number of bits of the second sound volume adjustment data is increased. That is, various characteristics of the sound volume converting apparatus can be realized by variously changing the number of bits allocated to the first sound volume adjustment data and the number of bits allocated to the second sound volume adjustment data in the sound volume adjustment data.

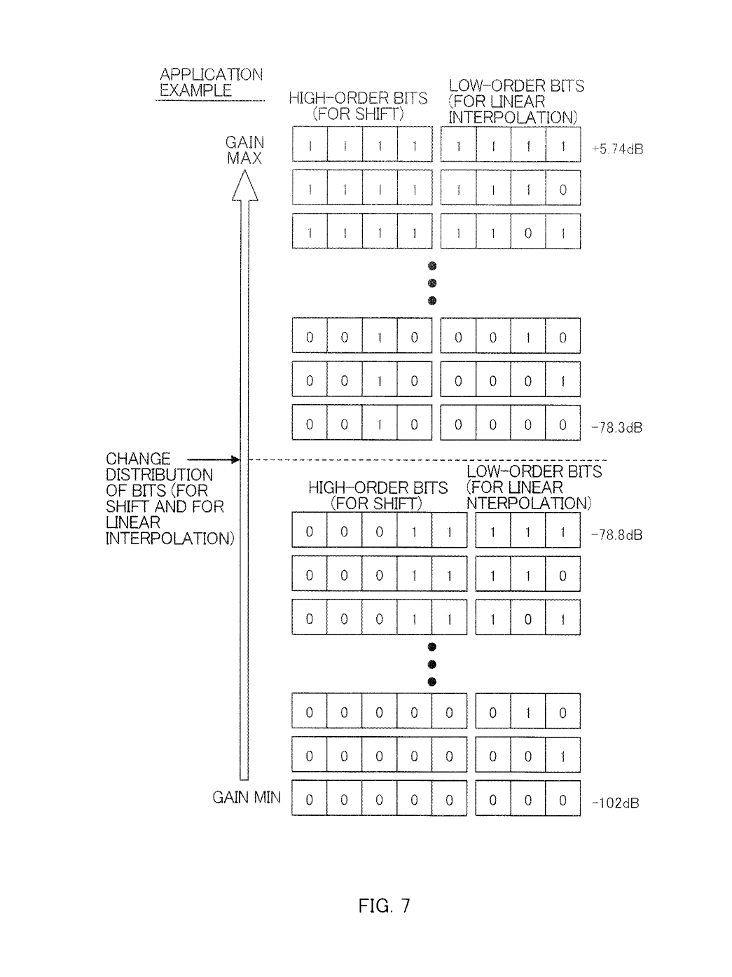

For example, in a range of low gains, fine gain steps may not be necessary. That is, the number of the black circles interpolating the adjacent white circles may be reduced. Alternatively, it may be desirable to expand a range of gains. That is, it may be desirable to increase the number of the white circles. In such a case, as shown in FIG. 7, for example, if the high-order three bits are all zero among the four-bit first sound volume adjustment data, the PCM audio signal can be shifted in accordance with each bit (4+1 bits) of the bits (four bits) of the first sound volume adjustment data and the highest-order bit (one bit) of the second sound volume adjustment data.

In this way, the minimum gain can be expanded to −102 dB (2̂−17 times).

The gain setting value detecting unit 260 determines the number of bits allocated to the first sound volume adjustment data and the number of bits allocated to the second sound volume adjustment data. The gain setting value detecting unit 260 determines the number of bits input to the shift amount controlling unit 211 and the number of bits input to the bit selector 232 in accordance with a value of the gain setting value and gives instructions to the shift amount controlling unit 211 and the bit selector 232. For example, if it is detected that the high-order three bits of the gain setting value is zero, the gain setting value detecting unit 260 instructs the shift amount controlling unit 211 to input the high-order five bits of the sound volume adjustment data and instructs the bit selector 232 to input the low-order three bits of the sound volume adjustment data.

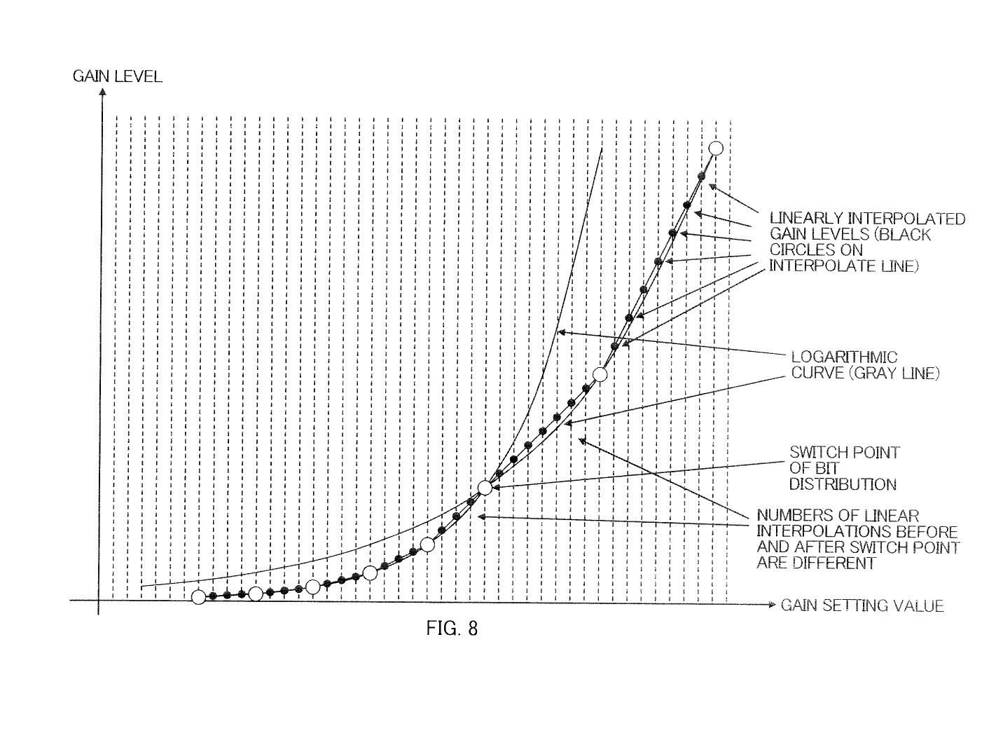

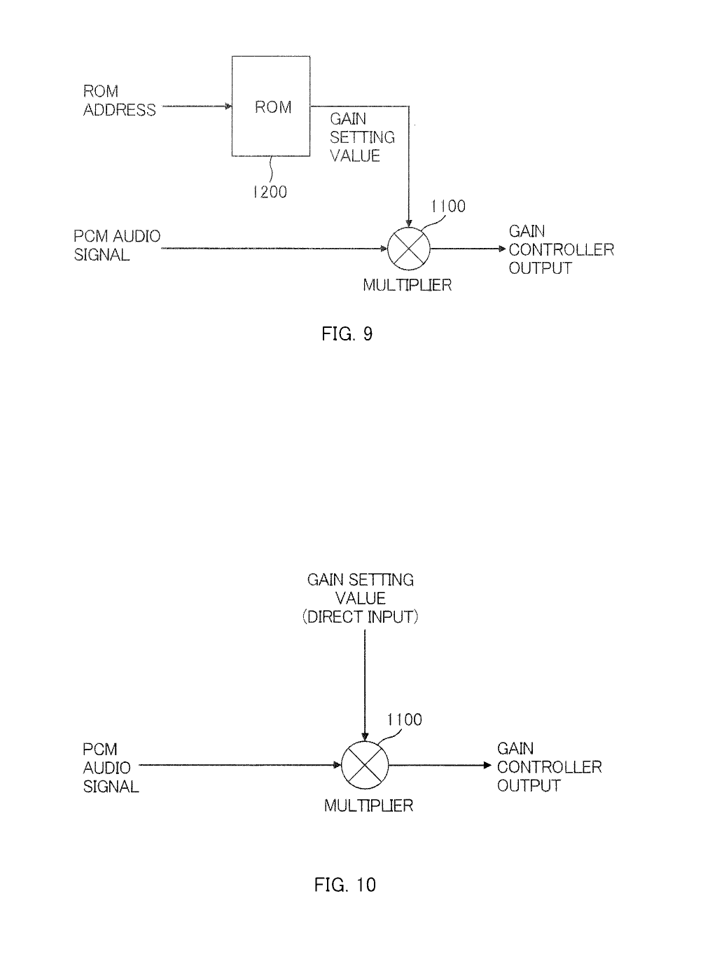

FIG. 8 shows a graph of gain levels when the bit allocations of the first sound volume adjustment data and the second sound volume adjustment data is changed in accordance with a value of the sound volume adjustment data. It is shown that the number of the black circles interpolating the adjacent white circles is varied from a bit distribution switching point.

If the high-order three bits are all zero among the first sound volume adjustment data, the overall shift circuit 210 shifts each bit of Xᵢₙ toward lower-order bits by the number of bits of a value obtained by subtracting a value obtained by decoding the high-order five bits of the sound volume adjustment data from 17 ((two to the fourth power-1)−2+two to the second power) to obtain Xₒᵤₜ. For example, if the sound volume adjustment data is “00011111” in FIG. 7, the PCM audio signal is shifted by 14 bits, which is obtained by subtracting 3 from 17.

The interpolation bit shifter 220, the bit selector 232, the multiplexer 230, the adder 240, etc., use Xₒᵤₜ and the low-order three bits of the sound volume adjustment data to calculate and add the intermediate data to Xₒᵤₜ.

Since the number of bits can be increased for shifting the PCM audio signal input to the gain controller 200 in this way, the output range width can correspondingly be expanded.

Although the gain controller 200 according to an embodiment has been described, the sound volume converting apparatus can be provided with a configuration not requiring a ROM and an adder according to the gain controller 200. As a result, the circuit scale of the gain controller 200 can considerably be reduced.

The feeling of discontinuity at the time of the sound volume adjustment by a user can be eliminated by adding the correction value after the digital audio data is shifted.

The sound volume adjustment can flexibly be controlled by changing the number of bits configuring the first sound volume adjustment data and the number of bits configuring the second sound volume adjustment data in accordance with the value of the sound volume adjustment data. For example, in a range of small gain levels, the number of bits allocated to the first sound volume adjustment data can be increased to increase the number of bits for shifting the PCM audio signal, and the output range width can correspondingly be expanded.

The above embodiments of the present invention are simply for facilitating the understanding of the present invention and are not in any way to be construed as limiting the present invention. The present invention may variously be changed or altered without departing from its spirit and encompass equivalents thereof.

For example, the gain controller 200 is not limited to the circuit configuration shown in FIG. 2. The gain controller 200 may be configured by discrete circuits or may be configured by an integrated circuit. The gain controller 200 may be configured as one constituent element of the audio signal processing circuit 400 shown in FIG. 1 or may be configured as a circuit separated from the audio signal processing circuit 400. The gain controller 200 may be realized as one integrated circuit along with other circuits configuring the audio system 1000, such as the signal processing unit 310, the audio decoder 600, and the A/D converter 710. Each process of the gain controller 200 may be realized by executing software.

It is claimed:

1. A sound volume converting apparatus comprising:
a data shift unit configured to shift digital audio data by a predetermined number of bits to the right based on first sound volume adjustment data;
a correction value calculating unit configured to calculate a correction value based on the right-shifted digital audio data and second sound volume adjustment data; and
an adding unit configured to add the correction value to the right-shifted digital audio data to be output.

2. The sound volume converting apparatus of claim 1, wherein
the correction value calculating unit includes
a plurality of shift units configured to shift the right-shifted digital audio data to the right by the number of bits corresponding to a position of each bit of the second sound volume adjustment data, and
a selector unit configured to supply selectively the adding unit with the correction value that is any one value of the values shifted to the right by the plurality of shift units in accordance with a logical value of each bit of the second sound volume adjustment data.

3. The sound volume converting apparatus of claim 1, wherein
the correction value calculating unit includes
a shift unit configured to shift the right-shifted digital audio data to the right by one bit at a time for the number of times equivalent to the number of bits of the second sound volume data, and
a selector unit configured to refer to a logical value for each bit of the second sound volume adjustment data in the order from the highest-order bit each time the digital sound data is shifted to the right and to supply selectively the adding unit with a value output from the shift unit in accordance with the logical value.

4. The sound volume converting apparatus of claim 1,
wherein the first sound volume adjustment data is data configured by a portion of bits configuring sound volume adjustment data and wherein the second sound volume adjustment data is data configured by another portion of the bits configuring the sound volume adjustment data.

5. The sound volume converting apparatus of claim 4, further comprising:
an allocation changing unit configured to change the number of bits configuring the first sound volume adjustment data and the number of bits configuring the second sound volume adjustment data in accordance with the value of the sound volume adjustment data.
